(19) United States
(12) Patent Application Publication
(10) Pub. No.: US 2018/0269375 A1
(43) Pub. Date: Sep. 20, 2018

(54) MOISTURE-REPELLANT PROTECTIVE LAYER

(71) Applicant: CeramTec GmbH, Plochingen (DE)

(72) Inventors: Hans-Jürgen SCHREINER, Hersbruck (DE); Tanja EINHELLINGER-MÜLLER, Nürnberg (DE); Tobias SCHMIDT, Lauf (DE); Ralf MOOS, Bayreuth (DE); Michael SCHUBERT, Bayreuth (DE); Reiner BINDIG, Bindlach (DE)

(21) Appl. No.: 15/755,178

(22) PCT Filed: Aug. 26, 2016
(86) PCT No.: PCT/EP2016/070163

§ 371 Date: Feb. 26, 2018

(30) Foreign Application Priority Data
Aug. 26, 2015 (DE) 10 2015 216 317.2
Aug. 28, 2015 (DE) 10 2015 216 516.7
Oct. 13, 2015 (DE) 10 2015 219 796.4
Nov. 30, 2015 (DE) 10 2015 223 685.4

(51) Int. Cl. H01L 41/053; H01L 41/083; H01L 41/09; H01L 41/187; H01L 41/23

(52) U.S. Cl. CPC H01L 41/0533; H01L 41/083; H01L 41/23; H01L 41/1876; H01L 41/0986

(57) ABSTRACT

The invention relates to a piezoceramic multi-layer actuator with a moisture-repellant protective layer and a method for producing same.

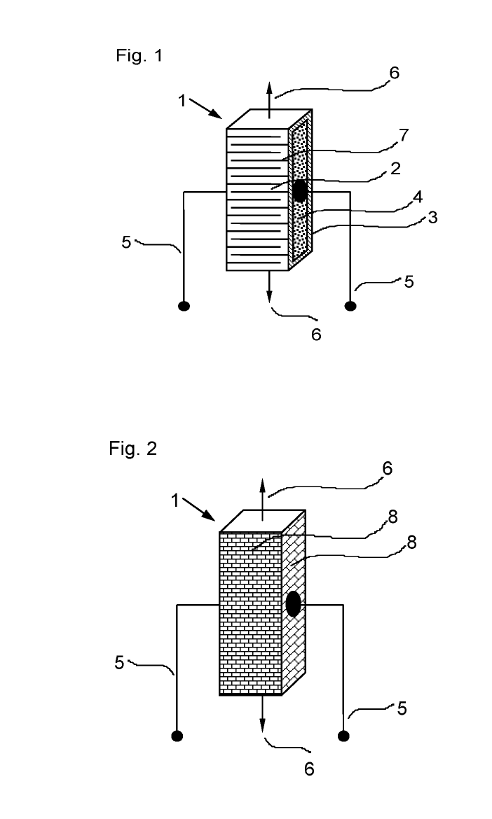

The present patent application relates to a piezoceramic multi-layer actuator having a moisture-repellant protective layer and method for producing same. Piezoceramic multi-layer actuators (FIG. 1) consist of stacked, thin layers of piezoelectrically active material (2), for example lead-zirconate-titanate (PZT), with inner electrodes (7) arranged therebetween, which are alternately conducted to the actuator surface. The outer electrodes (3), (4) connect the inner electrodes, causing the inner electrodes to be electrically connected in parallel and to be combined in two groups, which constitute the two connecting poles of the actuator. If an electrical voltage is applied to the connecting poles, this is transmitted to all inner electrodes in parallel and induces an electric field in all layers of the active material, which is thereby mechanically deformed. The sum of all of these mechanical deformations is available at the end surfaces of the actuator as a usable strain (6) and/or force.

Such a layer structure is usually produced by the cofiring method. The active material prior to sintering as a so-called green film is provided with inner electrodes by a screen printing method using a noble metal paste, pressed into actuator stacks, pyrolyzed, and then sintered, thus producing the monolithic actuator.

The surfaces of the actuator body are then processed by a shaping procedure, generally through polishing. In the region of the extended inner electrodes (7), a basic metallization (3) is applied to the actuator (1) e.g. through a galvanic procedure or by screen printing of a metal paste. This basic metallization is reinforced by the application of a metallic material (4), e.g. by soldering a wire mesh. The electrical connector wire (5) is soldered to this reinforced layer.

The structure and the manufacture of such actuators and outer electrodes are described in detail for example in publications DE 33 30538 A1, DE 40 36 287 C2, U.S. Pat. No. 5,281,885, U.S. Pat. No. 4,845,399, U.S. Pat. No. 5,406,164 and JP 07-226541 A.

On the lateral surfaces of the actuator, which are not provided with metallization, all of the electrodes protrude to the component surface. The electrical field intensity there is just as high as in the interior of the component, and amounts to several thousand volts per millimeter.

Polar molecules from the surroundings of the actuator, which come into proximity with the surface, for example steam, are polarized in this electrical field, straightened, and drawn to the surface. There they are adsorbed onto the ceramic surface, and as a result of various electrochemical reactions cause a current to flow between the electrodes projecting to the surface. The electrochemical reactions take place directly on the ceramic surface, but after a few minutes also along the grain boundaries close to the surface. Some of these electrochemical reactions in addition are irreversible and lead to degradation and at worst to loss of the actuator. The type of these electrochemical reactions is not entirely clarified, but the electrochemical water breakdown and ion migration on the actuator surface and along the hydrated grain boundaries appear to play a dominant role.

Piezoceramic actuators for the named reasons therefore react with great sensitivity to moisture in the surroundings and in moist surroundings can be operated only in pulse mode, so that the moisture can again be desorbed in the pulse pauses or operated at sufficiently high frequency.

Actuators are basically coated with an insulating layer in order to impede electrical arcing on the actuator surface. These coatings are usually unfilled or filled polymers and for steam show good or very good permeability, which could solve the current leakage problem.

To this point, the possibilities for countering the problem have not achieved any satisfactory results. For example, the inner electrodes are pulled back somewhat into the interior of the actuator, so that a closed ceramic layer arises on the actuator surface (buried electrodes, e.g. US2008048528). However, the closed ceramic layer must be at least around 0.2 mm thick because of the manufacturing tolerances. In operation it is passively extended and inevitably undergoes cracking, causing it to lose its protective action.

On the other hand, actuator sections with buried electrodes can be produced that have a height of only around 2 mm. Since in such a short section, insufficient traction tension can be built up during operation of the actuator, the sections theoretically undergo no cracking (e.g. JP 8-236828). The freedom from cracks is ensured only theoretically (statistically), however. If such actuators are examined, quite a high proportion of actuators are found that are nonetheless moisture-sensitive.

In order to circumvent the tolerance problems of the buried electrodes, an unsintered piezoceramic film can be laminated on the actuator surface and then sintered (e.g. DE10021919). In addition, a layer made from piezoceramic paste can be applied, e.g. by means of stenciling, and sintered. In both cases, from the statistical standpoint likewise there is a danger of crack formation in the layering due to operation of the actuator.

All actuators that are provided with sintered ceramic protective layers can therefore not be operated with the full power of which they are capable. Care must be taken that the protective layer in operation remains crack-free.

For very thin piezoceramic protective layers, in addition the consequences of the electrochemical reactions of moisture along the grain boundaries come to the foreground. The thinner the layer, the more significant the reactions that arise. Even with a relatively thick ceramic layer of 0.2 mm, these reactions can be verified as a leakage current.

The only method presently known and effective is encapsulating the actuators in a hermetically sealed metal housing, which must ensure that the adsorbed moisture inside the housing is chemically decomposed by a suitable filler medium (US2014368086). The not-inconsiderable additional production expense, the increased costs, and the markedly enlarged installation space of the actuators are disadvantageous.

From this arose the problem of the present invention of providing a multi-layer actuator with a moisture-repellant protective layer, which can be manufactured relatively simply and produced economically and has the smallest possible installation space. In addition, the actuator in operation must show the smallest possible leakage currents. The problem is solved by the multi-layer actuator according to claim 1 of the invention. Preferred embodiments are described in the dependent claims.

According to the invention a layer produced by means of an air stream deposition method, especially preferably by means of an ADM method, is used on the actuator surface as the protective layer against moisture (FIG. 2).

The protective layer is preferably a ceramic layer, wherein the ceramic can preferably be selected from a piezoceramic, aluminum oxide, zirconium oxide, titanium oxide, or other inorganic materials.

In the ADM method (aerosol deposition method or also RTIC=room temperature impact consolidation), particles are accelerated in a gas stream to supersonic speed and deposited on the actuator surface. In this way, apart from plastic deformation, fracturing of the particles into nanometer-sized pieces takes place, which consolidate to a dense and readily adhering surface. The entire method occurs at room temperature. The temperatures during application of the particles are <600° C., preferably <300° C.

The protective layer therefore consists basically of (fractured and consolidated) particles. This particle layer can undergo further treatment by tempering after application, in particular at temperatures of <800° C., preferably <600° C., especially preferably 300° C.

The layer thicknesses of the layers thus produced can lie in a range between 1 and 100 μm, wherein the range of 5-30 μm is especially preferred.

Layers produced by ADM are very dense (relative density >95%, preferably 98%) and pore-free, and contain no “grain boundaries” that arise due to sintering procedures. Electrochemical conduction processes such as those that arise in sintered ceramics do not occur. Because of their high density with adequate protective effect, the layers can be very thin and thus remain without cracks during operation of the actuator.

The protective layer of the piezoceramic multi-layer actuator that protects against moisture according to a preferred embodiment consists of particles, preferably ceramic particles.

In a preferred embodiment, the protective layer made from ceramic particles is preferably applied at temperatures of <600° C., preferably <300° C., and is post-treated at temperatures of <800° C., preferably <600° C., and especially preferably at 300° C.

In a further preferred embodiment, the protective layer made from ceramic particles is applied by means of an air deposition method, especially preferably by means of aerosol deposition.

In a further preferred embodiment, the protective layer made from ceramic particles encloses the entire actuator with the exception of the front sides, wherein only the protective layer-free points are kept open for soldering the connecting wires.

In a further preferred embodiment, the protective layer made from ceramic particles covers only the side surfaces of the actuator that carry no outer electrode layer.

In a further preferred embodiment, the protective layer made from ceramic particles does not conduct the electric current.

In a further preferred embodiment, the protective layer made from ceramic particles does not enter into chemical reactions with steam.

In a further preferred embodiment, the protective layer consists of piezoceramic particles, aluminum oxide particles, zirconium oxide particles, or titanium oxide particles.

In a further preferred embodiment, the protective layer has a layer density of 5-100 μm, especially preferably 10-30 μm.

The invention comprises a method for manufacturing a piezoceramic multi-layer actuator, wherein the protective layer protecting against moisture is applied by means of an air flow deposition method, especially preferably by means of aerosol deposition.

### EXAMPLES

The ceramic bodies for monolithic, piezoceramic multi-layer actuators were manufactured with the dimensions 7×7×30 mm³ and provided with outer electrode strips.

### Comparative Example 1

The actuators were washed with a non-aqueous medium, dried, and coated with a silicone lacquer (conformal coating) for insulation.

### Comparative Example 2

The actuators were washed with a demineralized water, dried, and coated with a silicone lacquer (conformal coating) for insulation.

### Example 3

The actuators were coated with an ADM layer made from piezoceramic (SP505, layer thickness 10 μm).

### Example 4

The actuators were coated with an ADM layer made of piezoceramic (SP505, layer thickness 30 μm).

### Example 5

The actuators were coated with an ADM layer made of piezoceramic (SP53, layer thickness 20 μm).

Measurement of the leakage current:

The actuators that were manufactured according to the above methods were connected to a voltage of 200 V (normal operating voltage) and the current was measured. The actuators were here exposed to a temperature of 25° C. and a relative humidity of 30%.

The current initially drops quickly (charge and polarization processes), reaches a minimum (Imin), and then rapidly increases (penetration of moisture into the actuator). The measure of moisture resistance is the time before the current first exceeds the value of 1 μA (ta).

| | lmin/nA | ta/h |
|---|---|---|
| Comparative example 1 | 8 | 10 |
| Comparative example 2 | 35 | 0.5 |
| Example 3 | 6 | 28 |
| Example 4 | 15 | >2000 |
| Example 5 | 2 | >2000 |

From the results it is established that the coating with an adequately dense and thick ADM layer can achieve an excellent protective effect against moisture, in particular in comparison with silicone lacquers known from the prior art.

1. A piezoceramic multi-layer actuator with a protective layer protecting against moisture, wherein the protective layer consists of particles, preferably ceramic particles.

2. The piezoceramic multi-layer actuator according to claim 1, wherein the protective layer consists of ceramic particles and preferably is applied at temperatures <600° C., preferably <300° C., and post-treated at temperatures of <800° C., preferably <600° C., especially preferably 300° C.

3. The piezoceramic multi-layer actuator having a protective layer protecting against moisture according to claim 1, wherein the protective layer consists of ceramic particles, and is applied by means of an air stream deposition method, especially preferably by means of aerosol deposition.

4. The piezoceramic multi-layer actuator according to claim 1, wherein the protective layer made of ceramic particles encloses the entire actuator except for the front sides, wherein only protective layer-free points are kept open for soldering the connecting wires.

5. The piezoceramic multi-layer actuator according to claim 1, wherein the protective layer made of ceramic particles covers only the lateral surfaces of the actuator that do not carry an outer electrode layer.

6. The piezoceramic multi-layer actuator of claim 1, wherein the protective layer made of ceramic particles does not conduct the electric current.

7. The piezoceramic multi-layer actuator of claim 1, wherein the protective layer made of ceramic particles does not enter into chemical reactions with steam.

8. The piezoceramic multi-layer actuator of claim 1, wherein the protective layer consists of piezoceramic particles, aluminum oxide particles, zirconium oxide particles, or titanium oxide particles.

9. The piezoceramic multi-layer actuator according to claims 1, wherein the protective layer has a layer thickness of 5-100 μm; especially preferably the range is 10-30 μm.

10. A method for manufacturing a piezoceramic multi-layer actuator according to claim 1, wherein the protective layer protecting against moisture is applied by means of the air stream deposition method, especially preferably by means of aerosol deposition.

11. The piezoceramic multi-layer actuator according to claim 1, wherein the protective layer comprises ceramic particles.
